(19) United States
(12) Patent Application Publication
(10) Pub. No.: US 2011/0049545 A1
(43) Pub. Date: Mar. 3, 2011

(54) LED PACKAGE WITH PHOSPHOR PLATE AND REFLECTIVE SUBSTRATE

(75) Inventors: Grigoriy Basin, San Francisco, CA (US); Jeffrey Kmetec, Palo Alto, CA (US); Paul S. Martin, Singapore (SG)

(73) Assignees: KONINKLIJKE PHILIPS ELECTRONICS N.V., Eindhoven (NL); PHILIPS LUMILEDS LIGHTING COMPANY, LLC, San Jose, CA (US)

(21) Appl. No.: 12/552,328

(22) Filed: Sep. 2, 2009

(51) Int. Cl. H01L 33/00

(52) U.S. Cl. 257/98; 438/29; 257/E33.061; 257/E33.067

(57) ABSTRACT

After flip chip LEDs are mounted on a submount wafer and their growth substrates removed, a phosphor plate is affixed to the exposed top surface of each LED. A reflective material, such as silicone containing at least 5% TiO₂ powder, by weight, is then spun over or molded over the wafer to cover the phosphor plates and the sides of the LEDs. The top surface of the reflective material is then etched using microbead blasting to expose the top of the phosphor plates and create a substantially planar reflective layer over the wafer surface. Lenses may then be formed over the LEDs. The wafer is then singulated. The reflective material reflects all side light back into the LED and phosphor plate so that virtually all light exits the top of the phosphor plate to improve the light emission characteristics.

### FIELD OF THE INVENTION

This invention relates to light emitting diodes (LEDs) and, in particular, to providing a reflective layer on a mounting surface that confines side light and helps support the LED die and a phosphor plate over the LED die.

### BACKGROUND

LEDs are typically mounted on a submount wafer that is later diced to separate out the individual LEDs/submounts. Each submount portion of the wafer has top electrodes that are bonded to electrodes on the LED, such as by ultrasonic bonding. An underfill material, such as epoxy or silicone, is then injected under the LED to provide mechanical support and protect the LED from contaminants.

The submount also has a set of more robust electrodes, electrically connected by a metal pattern to the LED electrodes, that are typically bonded to a printed circuit board (after the submount wafer is diced) using conventional solder reflow or other means.

It is known to provide reflective metal electrodes on the bottom surface of each LED so that light emitted downward by the LED active layer is reflected upward rather than being absorbed by the submount.

It is also known to glue a thin phosphor plate to the top surface of the LED die to wavelength convert the light emitted from the LED. Such phosphor plates are thin and brittle, although much thicker than the semiconductor layers of the LED. The side light emitted by the LED semiconductor layers (e.g., blue) and the phosphor plate (e.g., white, red, green, etc.) creates non-uniformity of color in the emitted light and tends to distort the desired Lambertion emission of the LED. This increases non-uniformity in the light emission, even when shaped by an overlying lens.

What is needed is a way to reflect side light upwards so that virtually all light exits through the top surface of the phosphor plate. This will help create a more uniform light emission both in color and brightness. It is also desirable to help mechanically support the delicate LED die and phosphor plate.

### SUMMARY

In one embodiment, a submount wafer is populated with flip chip LED dies. In one example, the active layer of the LEDs emits blue light. The growth substrate (e.g., sapphire for GaN LEDs) is then removed by laser lift-off or other technique. The exposed LED surface may be further process to roughen the surface for increased light extraction and to remove any damaged semiconductor material.

A thin phosphor plate is then glued to the exposed LED die surface.

A reflective mixture of silicone and TiO₂ is then spun over the entire submount surface to cover the tops of the phosphor plates and the sides of the LEDs. Alternatively, the reflective mixture may be molded over the submount surface or deposited using other methods. The reflective layer is electrically insulating.

A preferred reflective material is a silicone molding compound, which has a coefficient of thermal expansion close to that of the submount so that there is very little thermal expansion of the silicone molding compound under worst case conditions, such as during AuSn or AgSn solder reflow. If the percentage, by weight, of TiO₂ exceeds about 5% of the total filler content of the silicone, the layer is over 85% reflective. If the silicone contains 10% of total filler content, by weight, TiO₂, the layer is at least 90% reflective.

After the reflective mixture is cured (hardened), the surface is etched by microbead blasting to expose the top surfaces of the phosphor plates. The resulting reflective material is substantially planar over the entire submount surface and about even with the top of the phosphor plates. Since the reflective material covers the sides of the semiconductor LEDs and phosphor plates, all side light will be reflected back into the LED and phosphor plate and ultimately upward through the top surface of the phosphor plate to create a substantially uniform Lambertion pattern. Any downward light emitted by the LED will be reflected upward by the LEDs' reflective bottom metal electrodes (e.g., aluminum, silver, etc.).

The large area of the reflective material 32 ensures continued strong contact with the sides of the LED and phosphor plate.

In one embodiment, the underfill can also be a reflective mixture of silicone and TiO₂, as described in U.S. application Ser. No. 12/503,951, filed on Jul. 16, 2009, entitled Reflective Substrate for LEDs, by Grigoriy Basin and Paul Martin (present co-inventors), assigned to the present assignee and incorporated herein by reference.

Lenses may then be molded over the reflective layer and phosphor plates.

The submount wafer is then diced to separate out the individual LEDs.

### BRIEF DESCRIPTION OF THE DRAWINGS

FIG. 1 illustrates a portion of a prior art submount wafer populated by an array of LEDs, such as 500-4000 LEDs, where the LEDs are undergoing a laser lift-off operation to remove the growth substrates.

FIG. 2 illustrates the submount wafer of FIG. 1 after the growth substrates have been removed and after phosphor plates have been affixed to the semiconductor top surfaces of the LEDs.

FIG. 3 illustrates the submount wafer of FIG. 2 after a reflective material (e.g., silicone containing TiO₂) has been deposited over the wafer and over the tops and sides of the LEDs.

FIG. 4 illustrates the submount wafer of FIG. 3 undergoing microbead blasting to remove the reflective material over the phosphor plates and create a substantially planar surface.

FIG. 5 illustrates the submount wafer of FIG. 4 after the microbead blasting process.

FIG. 6 illustrates additional detail of a singulated LED module after lenses have been molded or otherwise formed over each LED. Side emission light rays are shown being reflected by the reflective material formed over the sides of the LED and phosphor plate.

Elements that are the same or equivalent are labeled with the same numeral.

### DETAILED DESCRIPTION

As a preliminary matter, a conventional LED is formed on a growth substrate. In the example used, the LED is a GaN-based LED, such as an AlInGaN or InGaN LED, for producing blue light. Typically, a relatively thick n-type GaN layer is grown on a sapphire growth substrate using conventional techniques. The relatively thick GaN layer typically includes a low temperature nucleation layer and one or more additional layers so as to provide a low-defect lattice structure for the n-type cladding layer and active layer. One or more n-type cladding layers are then formed over the thick n-type layer, followed by an active layer, one or more p-type cladding layers, and a p-type contact layer (for metallization).

For a flip-chip, portions of the p-layers and active layer are etched away to expose an n-layer for metallization. In this way, the p contact and n contact are on the same side of the chip and can be directly electrically attached to the submount contact pads. Current from the n-metal contact initially flows laterally through the n-layer. The LED bottom electrodes are typically formed of a reflective metal.

Other types of LEDs that can be used in the present invention include AlInGaP LEDs, which can produce light in the red to yellow range. Non-flip-chip LEDs can also be used.

The LEDs are then singulated and mounted on a submount wafer.

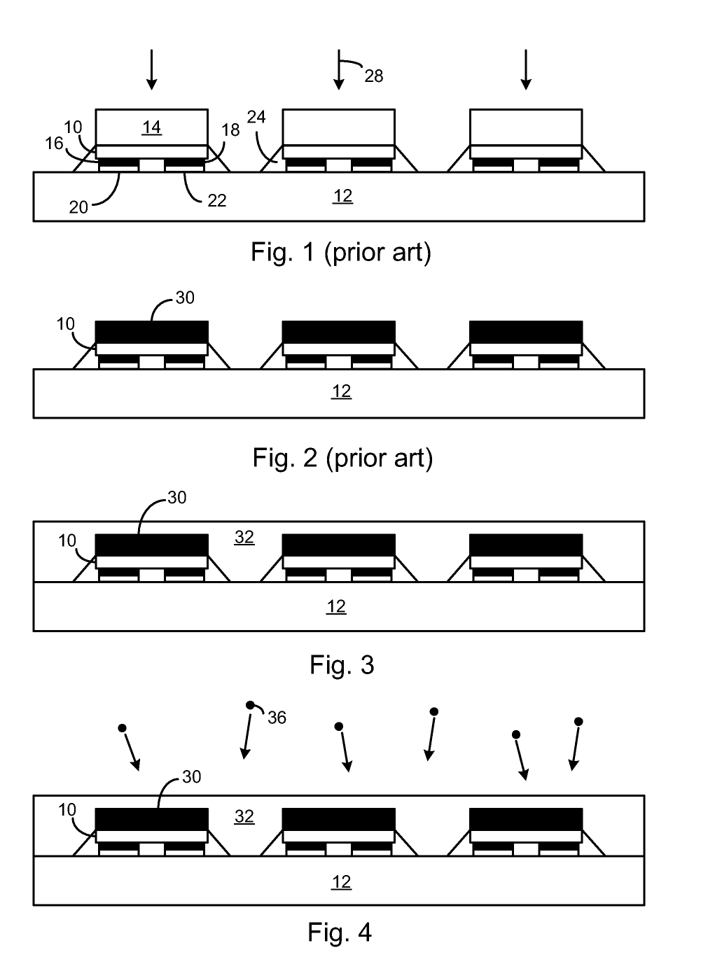

Prior art FIG. 1 illustrates conventional flip chip LEDs 10 mounted on a portion of a submount wafer 12. The wafer 12 is typically a ceramic or silicon. The LED 10 is formed of semiconductor epitaxial layers grown on a growth substrate 14, such as a sapphire substrate. In one example, the epitaxial layers are GaN based, and the active layer emits blue light. Any other type of LED is applicable to the present invention.

A metal electrode 16 is formed on the LED 10 that electrically contacts the p-layer, and a metal electrode 18 is formed on the LED 10 that electrically contacts the n-layer. In one example, the electrodes are reflective metal with gold bumps that are ultrasonically welded to anode and cathode metal pads 20 and 22 on the submount wafer 12. The submount wafer 12, in one embodiment, has conductive vias leading to bottom metal pads (not shown) for bonding to a printed circuit board. Many LEDs are mounted on the submount wafer 12, and the wafer 12 will be later singulated to form individual LEDs/submounts.

Further details of LEDs can be found in the assignee's U.S. Pat. Nos. 6,649,440 and 6,274,399, and U.S. Patent Publications US 2006/0281203 A1 and 2005/0269582 A1, all incorporated herein by reference.

An underfill 24 is then injected under each LED 10 or molded so as to be dispersed under each LED 10. The underfill 24 may be silicone, epoxy, or other suitable material that provides mechanical support of the thin LED layers during a laser lift-off process. In one embodiment, the underfill is a reflective material, such as a silicone molding compound with particles of TiO₂ (appearing white under white light), or other reflective particles such as ZrO₂, as described in U.S. application Ser. No. 12/503,951, filed on Jul. 16, 2009, entitled Reflective Substrate for LEDs, by Grigoriy Basin and Paul Martin (present co-inventors), assigned to the present assignee.

The LEDs 10 then undergo a laser lift-off process to remove the growth substrate 14. The laser pulses are shown by arrows 28. During the laser lift-off, the surface of the GaN absorbs heat, causing the surface layer to decompose into the Ga and N₂. The N₂ pressure pushes the sapphire growth substrates 14 away from the LEDs 10. After the growth substrates 14 become detached from the semiconductor LED layers during the lift-off process, they are removed by, for example, an adhesive sheet or some other suitable process. Laser lift-off is well known.

The exposed LED layers are then thinned by, for example, RIE or a mechanical etch, since the exposed top layer is a relatively thick n-layer, and the surface has imperfections due to the growth process and the damage caused by the laser lift-off process. The resulting top surface is desirably roughened to increase the light extraction efficiency. Roughening may be achieved by suitable etching, including photo-electrochemical etching (PEC).

As shown in FIG. 2, to create phosphor-converted light, a preformed phosphor plate 30 is affixed to the exposed top surface of each LED 10. The plate 30 typically has a thickness of a few hundred microns, while the LED semiconductor layers have a thickness of only a few tens of microns. The phosphor plate 30 may be formed of sintered phosphor powder, phosphor powder infused in a clear binder (e.g., silicone), a dried phosphor slurry, or formed in other ways. In one embodiment, the phosphor provides red and green components or yellow (YAG) so that the combination of the phosphor light and the blue LED light leaking through the phosphor creates white light.

The phosphor plate 30 may be affixed to the LED 10 by silicone, epoxy, a high index glass, sintering, or by other means.

The light emitted from the top surface of the phosphor plate 30 of FIG. 2 is substantially uniform in color and has a Lambertian distribution. However, the blue LED light from the sides of the LED and the light from the sides of the phosphor plate 30 create non-uniformity in the overall color output. And, the side light distorts the desired Lambertian distribution. Additionally, when a lens is used, the side light is not adequately shaped by the lens. Also, the phosphor plate 30 is delicate and subject to delamination, especially under conditions such as those experienced when used in automobiles.

To overcome these drawbacks of the structure of FIG. 2, a reflective material 32, shown in FIG. 3 is deposited over the surface of the submount wafer 12 to overlie the top and sides of the phosphor plates 30 and the sides of the LEDs 10. In one embodiment, the reflective material 32 is deposited in a liquid form and then spun on the wafer 12 to create a substantially planar layer. In other embodiments, the reflective material 32 is sprayed on, molded over (using wafer scale compression molding or injection molding), or dispensed in other ways.

In one embodiment, the reflective material 32 is a silicone molding compound containing TiO₂ so as to appear white under white light. A typical silicone molding compound contains about 82%-84% SiO₂ by weight, which creates a very stable material in the high-photon energy, high-heat environment of a power LED. To create the reflective properties of the material 32, TiO₂ is included in the silicone molding compound to replace some of the SiO₂ to cause the TiO₂ to be about 5-10% or higher by weight of the total amount of filler in the silicone molding compound. The TiO₂ plus the SiO₂ should equal about 80%-84% by weight of the silicone compound. A 5% addition of TiO₂ results in about an 85% reflectivity of the silicone compound, and a 10% addition of TiO₂ results in over 90% reflectivity of the silicone compound. Significantly more TiO₂ begins to reduce the desirable characteristics of the silicone compound. Other formulations of an electrically insulating, reflective material 30 may be used. White inorganic powders other than TiO₂ may also be used.

The reflective material 32 is then heated to cure (harden) it. Alternatively, the reflective material 32 may be cured with UV light.

As shown in FIG. 4, the entire surface of the wafer 12 is then etched using high-velocity microbeads 36 in a process called microbead blasting. In one embodiment, the microbeads 36 have diameters between 1-20 microns and are formed of NaHCO₃. The microbeads 36 are accelerated through a nozzle by air at a pressure of about 50-100 psi or less. The nozzle may be large to etch the reflective material 32 from over the phosphor plates 30 without the nozzle moving, or a smaller nozzle may be used to etch the reflective material 32 off only a few plates 30 at a time followed by the nozzle moving to a next position over the wafer 12. Removing excess material of any kind using microbeads is a known process.

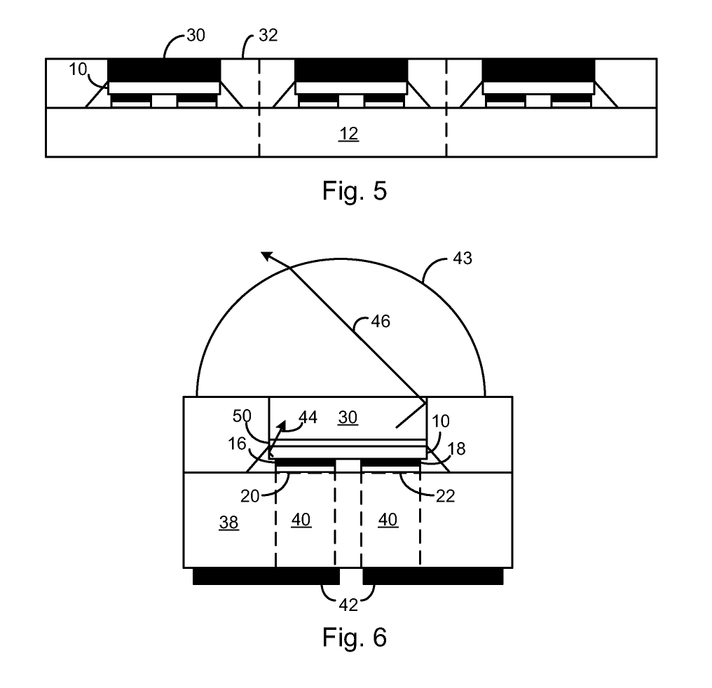

As shown in FIG. 5, the reflective material 32 has been etched to create a substantially planar reflective layer over the submount wafer 12 surface between the LEDs 10 and about even with the top surface of the phosphor plates 30. The large area of the reflective material 32 ensures continued strong contact with the sides of the LED 10 and phosphor plate 30.

Transparent lenses (e.g., silicone) may then be molded over each LED 10 to increase the light extraction from the LED, protect the phosphor plate 30 and LED 10, and create a desired light emission pattern. The lens may be any shape, such as the hemispherical shape shown in FIG. 6. The lenses are molded on a wafer scale prior to dicing the wafer 12. Details of a wafer-level lens molding process are described in Patent Publication US 2006/0105485, entitled Overmolded Lens Over LED Die, by Grigoriy Basin et al., assigned to the present assignee and incorporated herein by reference.

In one embodiment, the lens material also contains phosphor particles to further wavelength convert the light emitted by the LEDs 10. In one embodiment, the phosphor plate 30 is a YAG phosphor (emits yellow-green light) and the phosphor in the molded lens emits a red light when energized by the blue LED light to create a warmer white light.

Other wafer-level processes may also be performed on the LED array while mounted on the submount wafer 12.

The submount wafer 12 is then singulated along the dashed lines in FIG. 5, such as by sawing, to form individual LEDs/submounts, as shown in FIG. 6. FIG. 6 shows additional detail of the resulting LED and submount 38. Metal vias 40 extend through the ceramic submount 38 and terminate in robust bonding pads 42 on the bottom surface of the submount 38 for bonding to pads on a circuit board. A hemispherical lens 43 has been molded over the LED.

A light ray 44 is shown being emitted from the side of the semiconductor layers of the LED 10 and reflecting off the reflective material 32 toward the phosphor plate 30. Another light ray 46 is shown being emitted from the side of the phosphor plate 30 and reflected upward by the reflective material 32. Downward light rays will ultimately be reflected up by the reflective material 32 or the reflective LED electrodes 16 and 18. FIG. 6 also illustrates the transparent glue layer 50 that affixes the phosphor plate 30 to the LED 10, and side light from the glue layer 50 is also reflected by the reflective material 32. The reflective material 32 confines the light from the LED so that virtually all light is emitted from the top surface of the phosphor plate 30.

Since the reflective material 32 is formed of a transparent material containing reflective powder, light enters the material 32 at various depths before being reflected. The depth depends on the percentage of TiO₂.

The reflective material 32 not only confines the light to improve color uniformity and overall light output uniformity, but the entire LED 10 and phosphor plate 30 has additional mechanical support to prevent delamination, edge chipping, etc. The reflective material 32 also increases the light output and efficiency of the LED due to the side light from the LED and plate being ultimately reflected upward so as to be useful, as well as due to the reflective layer surface surrounding the plate reflecting light and because there is less light absorption by the submount wafer.

In another embodiment, the growth substrate is not removed, and the reflective material 32 is formed over the wafer 12 surface to cover the wafer up to the top surface of the LEDs, such as up to the top of the growth substrate, the top of a phosphor plate over the substrate, or the top of another optical element. The reflective material 32 still channels any side light through the top surface of the LED to achieve improved light emission.

In another embodiment, the phosphor plate is a phosphor layer that was not preformed but was deposited over the LED surface such as by electrophoresis, spraying, or other process.

In another embodiment, the reflective material 32 also forms the underfill in a single compression or injection molding step.

While particular embodiments of the present invention have been shown and described, it will be obvious to those skilled in the art that changes and modifications may be made without departing from this invention in its broader aspects and, therefore, the appended claims are to encompass within their scope all such changes and modifications as fall within the true spirit and scope of this invention.

What is claimed is:

1. A light emitting device comprising:
a light emitting diode (LED) die having a light emitting top surface and light emitting side surfaces;
a submount on which the LED die is mounted, the submount having a top surface;
a phosphor layer overlying the LED die's top surface, the phosphor layer having a top surface and side surfaces; and
a substantially flat reflective layer over the submount's top surface surrounding the LED die and phosphor layer and substantially even with the top surface of the phosphor layer, the reflective layer contacting the LED die's side surfaces and phosphor layer side surfaces to reflect side light back into the LED die and phosphor layer.

2. The device of claim 1 wherein the reflective layer comprises silicone infused with TiO₂.

3. The device of claim 2 wherein the TiO₂ comprises more than about 5% by weight of the reflective layer.

4. The device of claim 1 wherein the phosphor layer is a preformed phosphor plate affixed to the top surface of the LED die.

5. The device of claim 4 wherein the phosphor plate is affixed directly to the top surface of the LED.

6. The device of claim 1 wherein the reflective layer extends to edges of the submount.

7. The device of claim 1 wherein the reflective layer has been etched to be substantially even with the top surface of the phosphor layer.

8. The device of claim 1 wherein a growth substrate for the LED die has been removed.

9. The device of claim 1 wherein a reflectivity of the reflective layer to visible light is greater than about 80%.

10. The device of claim 1 wherein the reflective layer comprises a silicone molding compound infused with reflective particles.

11. The device of claim 1 further comprising a transparent lens molded over the LED die, the phosphor layer, and a portion of the reflective layer.

12. A method for fabricating a light emitting device comprising:
providing a light emitting diode (LED) die on a submount surface, the LED die having a top surface and side surfaces;
providing a phosphor layer over at least the LED die's top surface, the phosphor layer having a top surface and side surfaces;
providing a liquid reflective material over the submount's surface surrounding the LED die and phosphor layer so that the reflective material extends over the top surface of the phosphor layer;
curing the reflective material to form a reflective layer; and
etching the reflective layer to be substantially even with the top surface of the phosphor layer, the reflective layer contacting the LED die's side surfaces and phosphor layer side surfaces to reflect side light back into the LED die and phosphor layer.

13. The method of claim 12 wherein providing a phosphor layer comprises affixing a preformed phosphor plate over the top surface of the LED die.

14. The method of claim 12 wherein the reflective material comprises silicone infused with TiO₂, and a reflectivity of the reflective layer to visible light is greater than about 80%.

15. The method of claim 12 wherein etching the reflective layer comprises microbead blasting the reflective layer.
